(19) United States
(12) Patent Application Publication
(10) Pub. No.: US 2006/0236534 A1
(43) Pub. Date: Oct. 26, 2006

(54) Method for manufacturing printed wiring board

(76) Inventor: Shunji Ichikawa, Tokyo (JP)

Correspondence Address: RABIN & Berdo, PC, 1101 14TH STREET, NW, SUITE 500, WASHINGTON, DC, 20005, US

(21) Appl. No.: 11/406,298

(22) Filed: Apr. 19, 2006

(30) Foreign Application Priority Data
Apr. 20, 2005 (JP) 121764/2005

(51) Int. Cl. H05K 3/36

(52) U.S. Cl. 29/852; 29/830; 29/831; 29/846

(57) ABSTRACT

A method for manufacturing a printed wiring board comprises the steps of defining contact holes for forming both via holes forming through holes and contact terminals, in an insulated board with conductor layers formed over obverse and reverse surfaces thereof; forming conductive layers in inner peripheral surfaces of the via holes and the contact holes; forming etching masks for covering regions for forming wiring patterns and the through holes, over the obverse and reverse conductor layers, and etching the insulated board to remove the exposed conductor layers and the conductive layers formed over the inner peripheral surfaces of the exposed contact holes; and forming contact terminals for electrically connecting the obverse and reverse wiring patterns in the inner peripheral surfaces of the contact holes respectively.

### BACKGROUND OF THE INVENTION

The present invention relates to a method for manufacturing a printed wiring board in which contact terminals are respectively formed at edge portions thereof.

A structure of a printed wiring board formed with contact terminals at its edge portions is shown in FIGS. 9 and 10.

In FIGS. 9 and 10, reference numeral 1 indicates the printed wiring board.

Reference numeral 2 indicates an insulated board of the printed wiring board 1, which is formed of an insulating material.

Reference numerals 3 indicate wiring patterns, which are formed by etching conductor layers 4 formed by crimping metal foils formed of a material such as copper having electrical conductivity over both obverse and reverse surfaces of the insulated board 2.

Reference numerals 5 indicate through holes each constituted of a via hole 6 having a relatively small radius, which penetrates from the front surface of the insulated board 2 to its back surface, and a connecting layer 11 (copper layer 7 and nickel gold layer 10) formed by laminating the copper layer 7 used as a conductive layer, and a nickel layer 8 and a gold layer 9 (these are collectively called “nickel gold layer 10”) over an inner peripheral surface of the through hole 6. Each through hole 5 electrically connects the wiring patterns 3 formed on the obverse and reverse surfaces of the insulated board 2.

Reference numerals 13 indicate contact terminals, which are terminals each formed with a contact layer 14 by a material having electrical conductivity over an arcuate surface having a radius relatively larger than that of the via hole 6 of each of the through holes 5 formed at the side portions and corners (called edge portions) of the printed wiring board 1. The contact terminals 13 are respectively electrically connected to the wiring patterns 3 formed over the obverse and reverse sides of the insulated board 2 and function as points which electrically contact the outside.

In the related art, each of the contact layers 14 is constituted by laminating the copper layer 7 and the nickel gold layer 10 in a manner similar to the above connecting layer 11.

Such printed wiring boards 1 are normally arranged and formed in one large sheet-like insulated board 2 in matrix form, followed by being divided into pieces, whereby the corresponding printed wiring board 1 is formed. Therefore, the contact terminals 13 are formed by defining contact holes 15 each extending through the one large insulated board 2 and having a relatively large radius in the insulated board 2 as bore holes and forming contact layers 14 on their inner peripheral surfaces. When the sheet-like insulated board 2 is divided into pieces as the printed wiring boards 1, it is cut and formed so as to divide the contact terminals 13.

A conventional manufacturing method of the printed wiring board 1 will be explained in accordance with process steps indicated by PZ in FIG. 11.

Incidentally, a cross-section shown in FIG. 11 corresponds to a section (same as ones in explanatory views of other manufacturing methods) obtained by extending a section similar to FIG. 10 from both sides of FIG. 10 and indicating the same up to the neighborhood containing contact holes 15 formed in a sheet-like insulated board 2.

In PZ1, an insulated board 2 with conductor layers 4 formed on both obverse and reverse surfaces thereof is prepared. Via holes 6 for forming through holes 5 and contact holes 15 for forming contact terminals 13 are defined in their corresponding predetermined regions of the insulated board 2 by using an NC processing machine.

In PZ2, the inner peripheral surfaces of the via holes 6 and the contact holes 15 are thinly plated with copper by electroless plating to electrically connect the obverse and reverse conductor layers 4. The copper plating and the conductor layers 4 are configured as one electrode, and the plating thickness of copper is made thick by electrolytic plating to form each copper layer 7. The conductor layers 4 provided on the obverse and reverse surfaces of the insulated board 2 are electrically connected by the copper layer 7.

In PZ3, a dry film 17 having photosensitivity is applied onto the conductor layers 4 provided on both surfaces and exposed to ultraviolet light or the like. The photosensitized dry film 17 is removed by development to form etching masks which cover regions for forming wiring patterns 3 and through holes 5, and contact terminals 13.

In PZ4, the insulated board 2 formed with the masks by the dry film 17 is immersed in an etchant to remove the exposed conductor layers 4 and thereby form the corresponding wiring patterns 3. The dry film 17 is removed by a release agent or remover.

In PZ5, a solder-resist liquid having photosensitivity, such as an epoxy one is applied onto the insulated board 2 and exposed to ultraviolet light or the like to thereby remove the non-photosensitive solder-resist liquid by development with the photosensitized regions left behind. A solder resist 18 is formed over the copper layers 7 formed on the inner peripheral surfaces of both the via holes 6 for forming the through holes 5 and the contact holes 15 for forming the contact terminals 13, the wiring patterns 3 excluding the neighborhood of obverse and reverse openings of these, and the insulated board 2.

In PZ6, a nickel layer 8 and a gold layer 9 are sequentially laminated by electrolytic plating or electroless plating with the solder resist 18 as a mask. A nickel gold layer 10 is formed over the copper layers 7 formed on the inner peripheral surfaces of the exposed via holes 6 and contact holes 15, and the wiring patterns 3 located in the neighborhood of the obverse and reverse openings of the via holes 6 and the contact holes 15. Thus, the corresponding through holes 5 and contact terminals 13, which electrically connect the obverse and reverse surfaces of the printed wiring board 1, are formed. Further, connecting layers 11 and contact layers 14 are formed on the inner peripheral surfaces of the via holes 6 and contact holes 15.

Such through holes 5 normally range from about 0.15 mm to about 0.3 mm in diameter. The diameter of the hole of each contact terminal 13 is about 2 mm.

Through the above process steps, the individual printed wiring boards 1 arranged in matrix form are completed. They are cut into pieces so as to divide the contact terminals 13, whereby the printed wiring board 1 in which the contact terminals 13 are formed at its edge portions based on the conventional manufacturing method. Such a manufacturing method is generally called “tenting method”.

As a technique related to the tenting method, there is known a technique for forming the through holes 5, wherein connecting layers 14 for through holes 5 are formed by a process step similar to the above (refer to, for example, a patent document 1 (Japanese Unexamined Patent Publication No. Hei 7(1995)-7264 (paragraph 0002 in page 2, and FIGS. 6 and 7)).

However, the above related art is accompanied by problems that since the immersion-based etching process step for covering the contact holes 15 each having the relatively large radius with the dry film 17 to form the wiring patterns 3 is carried out, the dry film 17 falls in the contact holes 15 and is broken at bore angles, and in the etching process step corresponding to the process step PZ4, the etchant enters the contact holes 15 and melts each copper layer 7, so that it becomes difficult to form the nickel gold layer 10 in its subsequent process step PZ6, thus making it unable to electrically connect the contact terminals 13 and their corresponding obverse and reverse wiring patterns 3 of the printed wiring board 1.

This can solve an increase in the thickness of the dry film 17. However, there is a need to thin the thickness of the dry film 17 for miniaturization of each wiring pattern. This becomes a hindrance to the miniaturization of the printed wiring board 1. That is, in order to miniaturize or scaled down a ratio L/S (Lie and Space) between a width (Lie) of the wiring pattern 3 of the printed wiring board 1, which is indicated by L in FIG. 9, and an interval (Space) between the above wiring pattern 3 and the wiring pattern 3 adjacent to it, to such a degree that L=100 μm and S=60 μm, there is a need to set the thickness of the dry film 17 to 40 μm or less. If each contact hole 15 corresponding to a hole having a diameter of about 2 mm is covered with such a dry film, then the above problems occur.

### SUMMARY OF THE INVENTION

The present invention has been made to solve the above problems. It is therefore an object of the present invention to provide means which enables electrical connections between contact terminals and obverse and reverse wiring patterns of a printed wiring board without increasing the thickness of a dry film.

According to one aspect of the present invention, for attaining the above object, there is provided a method for manufacturing a printed wiring board, comprising the steps of defining contact holes for forming both via holes forming through holes and contact terminals, in an insulated board with conductor layers formed over obverse and reverse surfaces thereof; forming conductive layers in inner peripheral surfaces of the via holes and the contact holes; forming etching masks for covering regions for forming wiring patterns and the through holes, over the obverse and reverse conductor layers, and etching the insulated board to remove the exposed conductor layers and the conductive layers formed over the inner peripheral surfaces of the exposed contact holes; and forming contact terminals for electrically connecting the obverse and reverse wiring patterns in the inner peripheral surfaces of the contact holes respectively.

Thus, the present invention can obtain an advantageous effect capable of forming contact terminals respectively electrically connected to obverse and reverse wiring patterns of a printed wiring board regardless of bore diameters of the contact terminals and miniaturization of the wiring patterns.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is an explanatory view showing process steps for manufacturing a printed wiring board, according to a first embodiment;

FIG. 2 is an explanatory view illustrating process steps for manufacturing the printed wiring board, according to the first embodiment;

FIG. 3 is a top view depicting the printed wiring board according to the first embodiment;

FIG. 4 is a cross-sectional view taken along line B-B of FIG. 3;

FIG. 5 is an explanatory view showing process steps for manufacturing a printed wiring board, according to a second embodiment;

FIG. 6 is an explanatory view illustrating process steps for manufacturing the printed wiring board, according to the second embodiment;

FIG. 7 is an explanatory view depicting process steps for manufacturing a printed wiring board, according to a third embodiment;

FIG. 8 is an explanatory view showing process steps for manufacturing the printed wiring board, according to the third embodiment;

FIG. 9 is a top view illustrating a printed wiring board;

FIG. 10 is a cross-sectional view taken along line A-A of FIG. 9; and

FIG. 11 is an explanatory view showing process steps for manufacturing a conventional printed wiring board.

### DETAILED DESCRIPTION OF THE PREFERRED EMBODIMENTS

Preferred embodiments of a method for manufacturing a printed wiring board, according to the present invention will hereinafter be described with reference to the accompanying drawings.

### First Preferred Embodiment

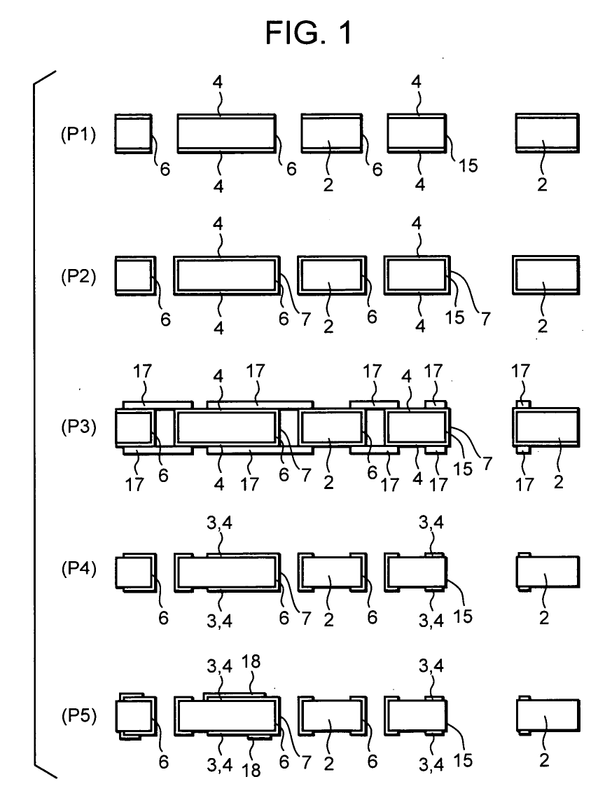

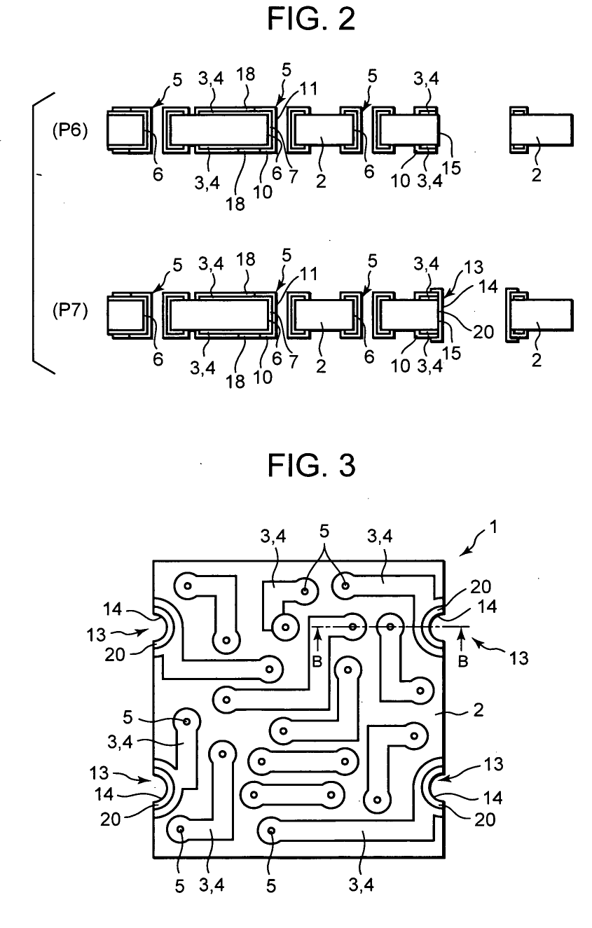

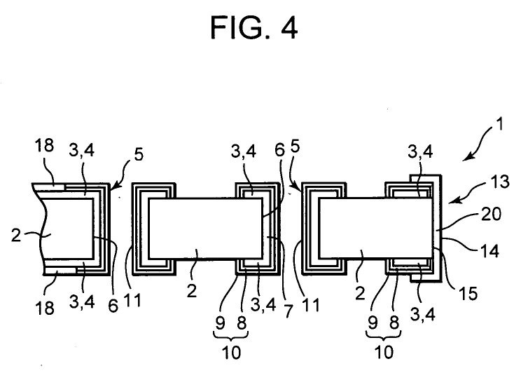

FIGS. 1 and 2 are respectively explanatory views showing process steps for manufacturing a printed wiring board, according to a first embodiment, FIG. 3 is a top view showing the printed wiring board employed in the first embodiment, and FIG. 4 is a cross-sectional view taken along line B-B of FIG. 3.

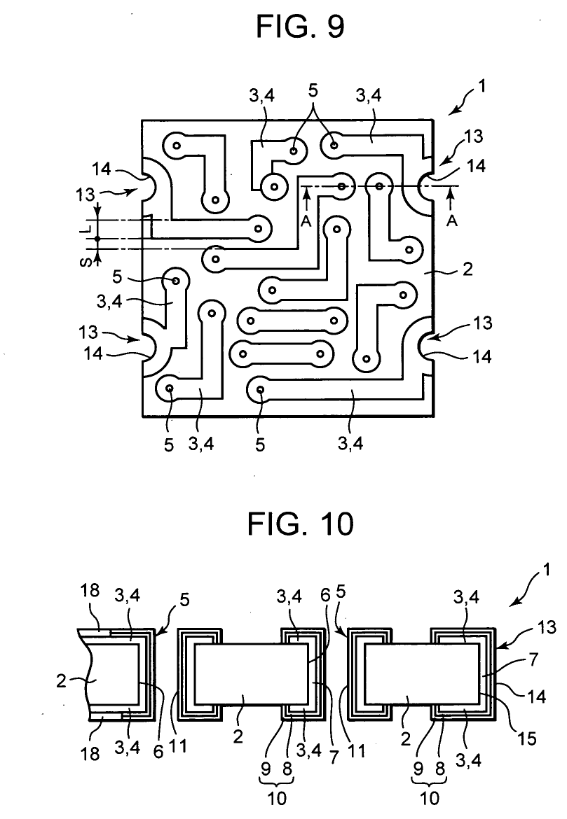

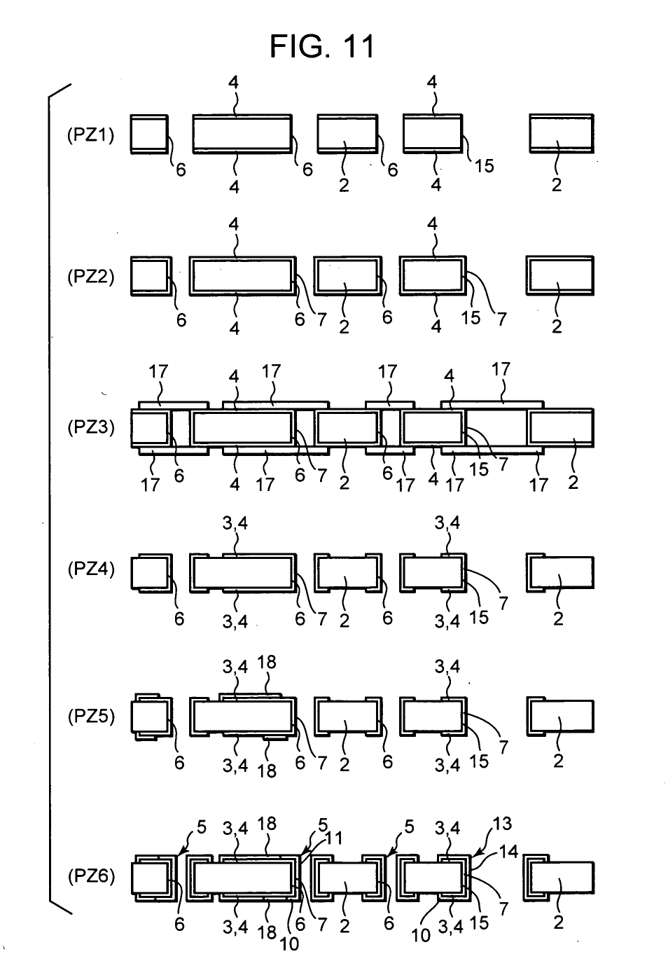

Incidentally, elements similar to those described using FIGS. 9, 10 and 11 are given the same reference numerals, and their explanations will be omitted.

In FIGS. 3 and 4, reference numerals 20 indicate conduction bodies, which are pipe-like members each having an outside diameter substantially equal to a diameter of a contact hole 15 constituted of a metal material having electrical conductivity, such as brass. The conduction body 20 is fitted in its corresponding contact hole 15 of a contact terminal 13 and thereafter its both ends are made wide to form a collar portion. The collar portion is crimped and fixed onto its corresponding wiring patterns 3 provided on an insulated board 2. Each contact terminal 13 electrically connected to its corresponding wiring patterns 3 provided on the obverse and reverse surfaces of the printed wiring board 1 is formed.

A method for manufacturing a printed wiring board, according to the present embodiment will be explained below in accordance with process steps indicated by P using FIGS. 1 and 2.

In P1, an insulated board 2 formed with conductor layers 4 over its obverse and reverse surfaces is prepared. Via holes 6 for forming through holes 5 and contact holes 15 for forming contact terminals 13 are defined in their corresponding predetermined regions of the insulated board 2 by using an NC processing machine.

In P2, the inner peripheral surfaces of the via holes 6 and the contact holes 15 are thinly plated with copper by electroless plating to electrically connect the obverse and reverse conductor layers 4. The copper plating and the conductor layers 4 are configured as one electrode, and the plating thickness of copper is made thick by electrolytic plating to form each copper layer 7 as a conductive layer. The conductor layers 4 provided on the obverse and reverse surfaces of the insulated board 2 are electrically connected by the copper layer 7.

In P3, a dry film 17 having photosensitivity is applied onto the obverse and reverse conductor layers 4 and exposed to ultraviolet light or the like. The photosensitized dry film 17 is removed by development to form etching masks which cover regions for forming wiring patterns 3 and through holes 5. In this case, regions for forming the contact terminals 13 will not be covered with the dry film 17.

In P4, the insulated board 2 formed with the etching masks by the dry film 17 is immersed in an etchant to remove the exposed conductor layers 4 and thereby form the corresponding wiring patterns 3. The dry film 17 is removed by a release agent or remover. At this time, the copper layer 7 formed on the inner peripheral surface of each contact hole 15 is removed.

In P5, a solder-resist liquid having photosensitivity, such as an epoxy one is applied onto the insulated board 2 and exposed to ultraviolet light or the like to thereby remove the non-photosensitive solder-resist liquid by development with the photosensitized regions left behind. A solder resist 18 is formed over the copper layers 7 formed on the inner peripheral surfaces of the via holes 6 for forming the through holes 5, the wiring patterns 3 excluding the inner peripheral surfaces of the contact holes 15 for forming the contact terminals 13 and the neighborhood of obverse and reverse openings of these, and the insulated board 2.

In P6, a nickel layer 8 and a gold layer 9 are sequentially laminated by electrolytic plating or electroless plating with the solder resist 18 as a mask. A nickel gold layer 10 is formed over the copper layers 7 formed on the inner peripheral surfaces of the exposed via holes 6, and the wiring patterns 3 located in the neighborhood of the obverse and reverse openings of the via holes 6 and the contact holes 15. Thus, the corresponding through holes 5, which electrically connect the obverse and reverse surfaces of the printed wiring board 1, are formed. Further, connecting layers 11 are formed on the inner peripheral surfaces of the via holes 6.

In P7, pipe-like conduction bodies 20 are fitted in their corresponding contact holes 15. Their obverse and reverse ends are made wide by press molding or the like and crimped to their corresponding wiring patterns 3 on the insulated board 2, thereby forming collar portions. Thus, the conduction bodies 20 are fixed to the printed wiring board 1, and the corresponding contact terminals 13 electrically connected to their obverse and reverse surfaces are formed. Further, the cylindrical portions of the conduction bodies 20 function as contact layers 14.

Incidentally, the solder resist 18 is left on the printed wiring board 1 without removal thereof and is caused to function as a protective film for the print wiring board 1.

Through the above process steps, the individual printed wiring boards 1 arranged in matrix form are completed. They are cut into pieces so as to divide the contact terminals 13, whereby the printed wiring board 1 in which the contact terminals 13 are formed at the edge portions shown in FIGS. 3 and 4 based on the manufacturing method according to the present embodiment is formed. In this case, the contact terminals 13 are formed in a state in which the conduction bodies 20 are being crimped. Since the contact terminals 13 are fixed to the printed wiring board 1 by the collar portions of the conduction bodies 20, they do not fall off.

Incidentally, although a description has been made of the case in which in the above process step P7, the pipe-like conduction bodies 20 are fitted in their corresponding contact holes 15 and both ends thereof are expanded so that the conduction bodies 20 are crimped and fixed to the printed wiring board 1, the process step P7 is omitted and instead a metal plate is applied onto each of the contact holes 13 subsequent to having been divided into the pieces and bent in saddle form by press molding or the like, followed by being crimped thereto, after which each conduction body 20 may be formed.

In the present embodiment as described above, the conduction bodies are crimped to the contact holes to form the contact terminals. Therefore, the contact terminals electrically connected to the wiring patterns on the obverse and reverse surfaces of the printed wiring board can be formed regardless of miniaturization of both the hole diameters of the contact terminals and the wiring patterns. Further, the above is capable of contributing to miniaturization of each printed wiring board having the contact terminals.

### Second Preferred Embodiment

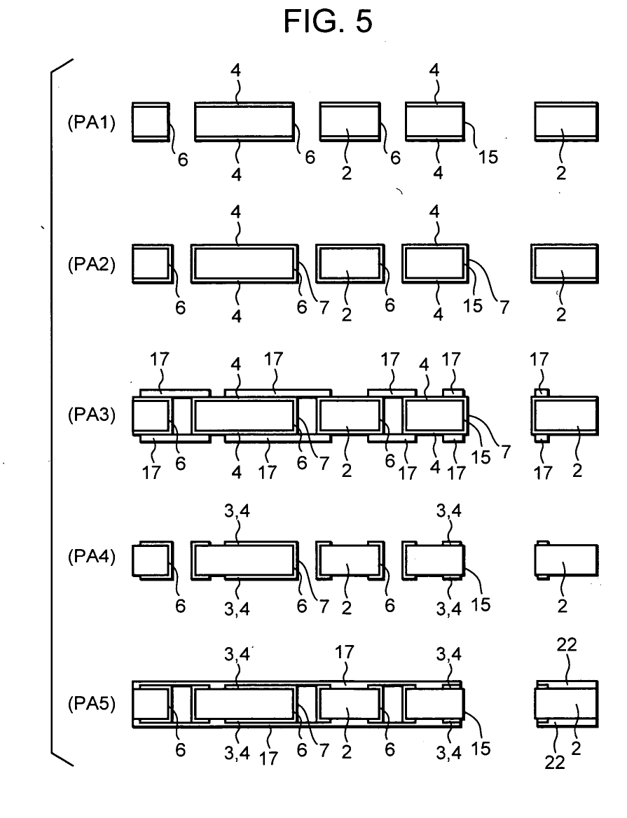

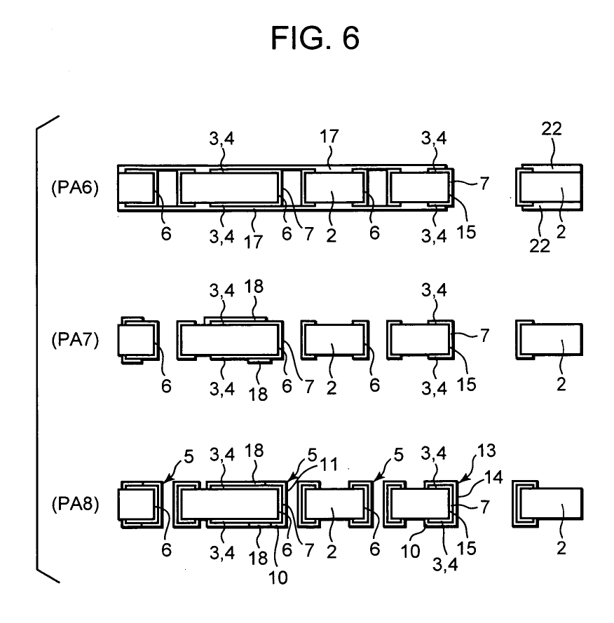

FIGS. 5 and 6 are respectively explanatory views showing process steps for manufacturing a printed wiring board, according to a second embodiment.

Incidentally, elements similar to those employed in the first embodiment are given the same reference numerals, and their explanations will be omitted.

A method for manufacturing the printed wiring board, according to the present embodiment will be explained below in accordance with the process steps indicated by PA using FIGS. 5 and 6.

Since the process steps PA1 through PA4 according to the present embodiment are similar to the process steps P1 through P4 according to the first embodiment, their explanations are omitted.

In PA5, a dry film 17 is applied onto obverse and reverse surfaces of an insulated board 2 in a manner similar to the process step P3 of the first embodiment. The photosensitized dry film 17 is removed and plating masks for covering areas excluding contact holes 15 are formed.

In PA6, the insulated board 2 formed with the plating masks by the dry film 17 is plated with copper by electroless plating to thereby form copper layers 7 used as conductive layers in their corresponding inner peripheral surfaces of the contact holes 15. Obverse and reverse conductor layers 4 of the insulated board 2 are electrically connected by the copper layers 7.

In PA7, the dry film 17 is removed using a release agent or remover. In a manner similar to the process step P5 of the first embodiment, a solder resist 18 is formed over the copper layers 7 formed on the inner peripheral surfaces of both via holes 6 for forming through holes 5 and the contact holes 15 for forming contact terminals 13, wiring patterns 3 excluding the neighborhood of obverse and reverse openings of these, and the insulated board 2.

In PA8, a nickel gold layer 10 is formed over the copper layers 7 formed on the inner peripheral surfaces of the via holes 6 and contact holes 15, and the wiring patterns 3 located in the neighborhood of the obverse and reverse openings of these via holes 6 and contact holes 15 in a manner similar to the process step P6 of the first embodiment. Thus, the through holes 5 and contact terminals 13, which electrically connect the obverse and reverse surfaces of the printed wiring board 1, are formed. Further, connecting layers 11 and contact layers 14 are formed on the inner peripheral surfaces of the via holes 6 and contact holes 15. In this case, the contact layers 14 of the contact terminals 13 are formed by the copper layers 7 formed by electroless copper plating and the nickel gold layer 10.

Through the above process steps, the individual printed wiring boards 1 arranged in matrix form are completed. They are cut into pieces so as to divide the contact terminals 13, whereby the printed wiring board 1 in which the contact terminals 13 are formed at the edge portions shown in FIGS. 9 and 10 based on the manufacturing method according to the present embodiment, is formed.

Incidentally, in the above manufacturing method, the contact holes 15 may be defined prior to the process step PA5 without defining the contact holes 15 in the process step PA1.

In the present embodiment as described above, the copper layers formed in the contact holes 15 are temporarily removed in the process of forming the wiring patterns by etching, and thereafter the copper layers are formed in the contact holes again. Thus, an advantageous effect similar to the first embodiment can be obtained and in addition to it, the contact terminals are formed by plating. It is therefore possible to easily form the contact terminals even though the contact holes are made small.

### Third Preferred Embodiment

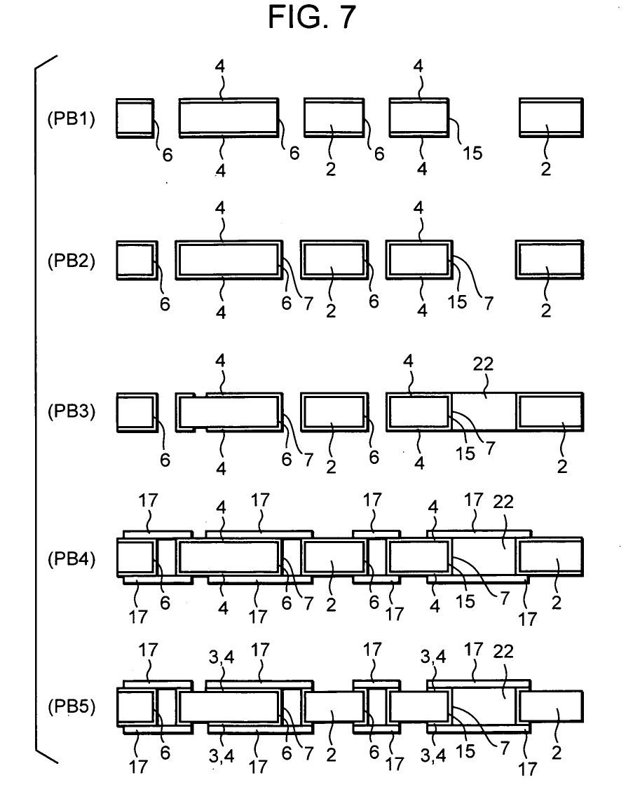

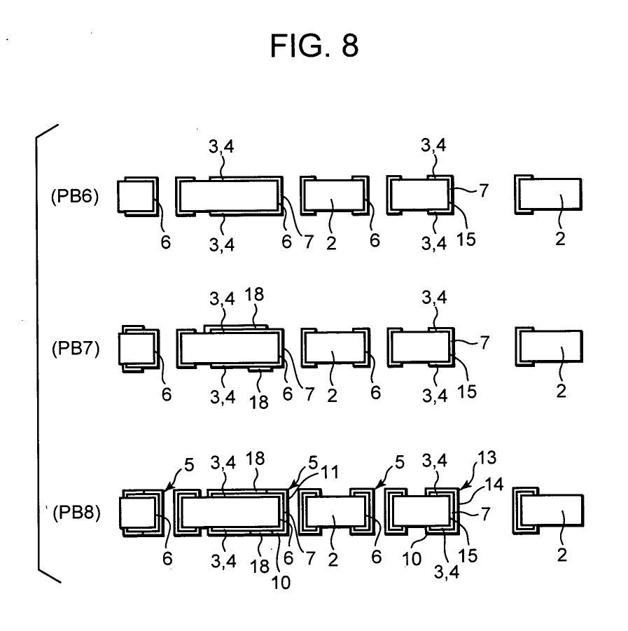

FIGS. 7 and 8 are respectively explanatory views showing process steps for manufacturing a printed wiring board, according to a third embodiment.

Incidentally, elements similar to those employed in the first embodiment are given the same reference numerals, and their explanations will be omitted.

In FIG. 7, reference numeral 22 indicates an insert or embedded plug, which is a columnar member formed by charging a resin such as an epoxy resin into an inside diameter section of each contact hole 15 formed with a copper layer 7 and curing it.

As such resin filling, a printing method for placing a resin on an insulated board 2 and collectively charging it on an unillustrated stage or a potting method for pouring a resin into each contact hole 15 by using a syringe is used. In the present embodiment, the epoxy resin is charged therein in accordance with the potting method to form each embedded plug 22.

A method for manufacturing the printed wiring board, according to the present embodiment will be explained below in accordance with process steps indicated by PB using FIGS. 7 and 8.

Since the process steps PB1 and PB2 employed in the present embodiment are similar to the process steps P1 and P2 employed in the first embodiment, their explanations are omitted.

In PB3, an epoxy resin is poured into each contact hole 15 formed with a copper layer 7 by using a syringe. Thereafter, it is cured by heat treatment to form an embedded plug 22 which buries the copper layer 7 of the contact hole 15.

In PB4, a dry film 17 is applied onto obverse and reverse conductor layers 4 of an insulated board 2 in a manner similar to the process step P3 of the first embodiment. The photosensitized dry film 17 is removed to form etching masks which cover regions for forming wiring patterns 3, through holes 5, and contact terminals 13.

In PB5, the insulated board 2 formed with the etching masks by the dry film 17 is immersed in an etchant to remove the exposed conductor layers 4 and thereby form the corresponding wiring patterns 3. Since, in this case, the embedded plug 22 is embedded into its corresponding contact hole 15 and the dry film 17 does not fall therein, no break occurs in the dry film 17.

In PB6, the dry film 17 is removed using a release agent or remover, and the embedded plug is chemically removed using a resolvent or the like which does not erode each copper layer 7.

Since subsequent process steps PB7 and PB8 are similar to the process steps PA7 and PA8 of the second embodiment, explanations thereof are omitted. In this case, each of the contact layers 14 of the contact terminals 13 is formed of a copper layer 7 and a nickel gold layer 10 both relatively thick, which are formed by electrolytic copper plating after electroless copper plating.

Through the above process steps, the individual printed wiring boards 1 arranged in matrix form are completed. They are cut into pieces so as to divide the contact terminals 13, whereby the printed wiring board 1 in which the contact terminals 13 are formed at the edge portions shown in FIGS. 9 and 10 based on the manufacturing method according to the present embodiment is formed.

Incidentally, although the embedded plug 22 has been explained as being chemically removed in the process step PB6, the embedded plug 22 is punched out by a punch or the like and may be removed mechanically.

In the present embodiment as described above, the copper layer formed in each contact hole is buried by the embedded plug before affixation of the etching dry film. Therefore, an advantageous effect similar to the first embodiment can be obtained.

Since each of the contact layers of the contact terminals is formed of the relatively thick copper layer and nickel gold layer, it can be constituted as a high reliable contact terminal. Further, since each of the contact terminals is formed by plating, it can easily be formed even though the contact hole becomes small.

While the preferred forms of the present invention have been described, it is to be understood that modifications will be apparent to those skilled in the art without departing from the spirit of the invention. The scope of the invention is to be determined solely by the following claims.

What is claimed is:

1. A method for manufacturing a printed wiring board, comprising the steps of:
defining contact holes for forming both via holes forming through holes and contact terminals, in an insulated board with conductor layers formed over obverse and reverse surfaces thereof;
forming conductive layers in inner peripheral surfaces of the via holes and the contact holes;
forming etching masks for covering regions for forming wiring patterns and the through holes, over the obverse and reverse conductor layers, and etching the insulated board to remove the exposed conductor layers and the conductive layers formed over the inner peripheral surfaces of the exposed contact holes; and
forming contact terminals for electrically connecting the obverse and reverse wiring patterns in the inner peripheral surfaces of the contact holes respectively.

2. The method according to claim 1, wherein the contact terminals are formed by fitting conduction bodies in the contact holes and crimping obverse and reverse ends of the conduction bodies to the obverse and reverse wiring patterns respectively.

3. The method according to claim 1, wherein the contact terminals are formed by applying metal plates to the contact holes, bending the metal plates in saddle form and crimping the same to the obverse and reverse wiring patterns.

4. The method according to claim 1, wherein the contact terminals are formed by forming plating masks which cover regions excluding the contact holes, and forming the conductive layers over the inner peripheral surfaces of the contact holes by plating.

5. A method for manufacturing a printed wiring board, comprising the steps of:
defining contact holes for forming both via holes forming through holes and contact terminals, in an insulated board with conductor layers formed over obverse and reverse surfaces thereof;
forming conductive layers in inner peripheral surfaces of the via holes and the contact holes;
charging a resin into the contact holes formed with the conductive layers therein to form embedded plug;
forming etching masks for covering regions for forming wiring patterns and the through holes, and the contact terminals, over the obverse and reverse conductor layers, and etching the insulated board to remove the exposed conductor layers; and
removing the masks and the embedded plugs.
